(19) United States
(12) Patent Application Publication
(10) Pub. No.: US 2025/0105817 A1
(43) Pub. Date: Mar. 27, 2025

(54) ACOUSTIC WAVE DEVICE

(71) Applicant: Murata Manufacturing Co., Ltd., Nagaokakyo-shi (JP)

(72) Inventor: Hideki IWAMOTO, Nagaokakyo-shi (JP)

(21) Appl. No.: 18/976,402

(22) Filed: Dec. 11, 2024

Related U.S. Application Data
(63) Continuation of application No. PCT/JP2023/017597, filed on May 10, 2023.

(30) Foreign Application Priority Data
Jun. 24, 2022 (JP) 2022-101908

(51) Int. Cl. H03H 9/02

(52) U.S. Cl. CPC H03H 9/02574; H03H 9/02559; H03H 9/02992

(57) ABSTRACT

An acoustic wave device includes a support substrate a silicon oxide layer on the support substrate, a lithium niobate layer on the silicon oxide layer, and an IDT electrode on the lithium niobate layer. When a wavelength of the IDT electrode is denoted as λ, a thickness of the silicon oxide layer is more than or equal to about 0λ. Values of T_{IDT}, ρ, duty, LNcut, T_{LN}, and T_{SiO2} are within ranges that enable BW derived from Formula 1 to be about 12% or less and ksaw2 derived from Formula 2 to be about 0.1% or less.

### CROSS REFERENCE TO RELATED APPLICATIONS

This application claims the benefit of priority to Japanese Patent Application No. 2022-101908 filed on Jun. 24, 2022 and is a Continuation application of PCT Application No. PCT/JP2023/017597 filed on May 10, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have been widely used for filters of mobile phones and other applications. Japanese Patent No. 5850137 discloses examples of a surface acoustic wave device. In the surface acoustic wave device disclosed in Japanese Patent No. 5850137, a support substrate, a high-acoustic velocity film, a low-acoustic velocity film, and a lithium niobate film are stacked on one another. An IDT (Interdigital Transducer) electrode is disposed on the lithium niobate film. When the cut-angle of the lithium niobate film is 30° Y-cut, the thickness of the lithium niobate film is less than or equal to 0.42λ. Here, λ is the wavelength of the fundamental mode of an SH surface acoustic wave.

However, in the acoustic wave device described in Japanese Patent No. 5850137, Rayleigh mode spurious responses cannot be suppressed sufficiently. Moreover, in the acoustic wave device using the lithium niobate film, the value of the fractional bandwidth tends to be large. If the value of the fractional bandwidth is excessively large, when, for example, the acoustic wave device is used for a filter device, the steepness near the edge portion on the high-frequency or low-frequency side of the pass band is not sufficiently large.

### SUMMARY OF THE INVENTION

Example embodiments of the present invention provide acoustic wave devices in each of which Rayleigh mode spurious responses are reduced or prevented without unduly increasing a value of a fractional bandwidth.

An acoustic wave device according to an example embodiment of the present invention includes a support substrate, a silicon oxide layer on the support substrate, a lithium niobate layer on the silicon oxide layer, and an IDT electrode on the lithium niobate layer, wherein, when a wavelength defined by an electrode finger pitch of the IDT electrode is denoted as λ, a thickness of the silicon oxide layer is more than or equal to about 0λ, and, when a thickness of the IDT electrode is denoted as T_{IDT} [λ], a density of the IDT electrode is denoted as ρ [g/cm³], a duty ratio of the IDT electrode is denoted as duty, a cut-angle of the lithium niobate layer is denoted as LNcut [°], a thickness of the lithium niobate layer is denoted as T_{LN} [λ], a thickness of the silicon oxide layer is denoted as T_{SiO2} [λ], a fractional bandwidth of an SH mode is denoted as BW [%], and an electromechanical coupling coefficient in a Rayleigh mode is denoted as ksaw2 [%], values of T_{IDT}, ρ, duty, LNcut, T_{LN}, and T_{SiO2} are within ranges that enable BW derived from Formula 1 to be about 12% or less and ksaw2 derived from Formula 2 to be about 0.1% or less.

$$BW [ \% ] = 16.58 + 11.78 \times duty - 4.977 \times LNcut + 25.41 \times {T}_{IDT} \times ρ + 240.3 \times {T}_{L N} + 13.76 \times {T}_{SiO 2} - 10.1 \times {( duty )}^{2} + 0.3515 \times {( LNcut )}^{2} - 0.01174 \times {( LNcut )}^{3} + 0.000207 \times {( LNcut )}^{4} - 0.000001865 \times {( LNcut )}^{5} + 6.771 \times {10}^{- 9} \times {( LNcut )}^{6} + 23.38 \times {( {T}_{IDT} \times ρ )}^{2} - 192.9 \times {( {T}_{IDT} \times ρ )}^{3} + 202.2 \times {( {T}_{IDT} \times ρ )}^{4} - 1612 \times {( {T}_{L N} )}^{2} + 5724 \times {( {T}_{L N} )}^{3} - 10863 \times {( {T}_{L N} )}^{4} + 10555 \times {( {T}_{L N} )}^{5} - 4123 \times {( {T}_{L N} )}^{6} - 24.57 \times {( {T}_{SiO 2} )}^{2} + 25.57 \times {( {T}_{SiO 2} )}^{3} - 11.11 \times {( {T}_{SiO 2} )}^{4} - 0.0377 \times duty \times LNcut - 13.8 \times duty \times {T}_{IDT} \times ρ + 3.097 \times duty \times {T}_{L N} - 0.2431 \times LNcut \times {T}_{IDT} \times ρ - 0.3101 \times LNcut \times {T}_{L N} - 0.07464 \times LNcut \times {T}_{SiO 2} - 14.65 \times {T}_{IDT} \times ρ \times {T}_{L N} + 8.021 \times {T}_{IDT} \times ρ \times {T}_{SiO 2} - 9.508 \times {T}_{L N} \times {T}_{SiO 2} \qquad Formula 1$$

$$ksaw 2 [ \% ] = 4.839 - 0.3046 \times duty - 0.3965 \times LNcut + 0.3606 \times {T}_{IDT} \times ρ + 3.956 \times {T}_{L N} + 0.1 \; 944 \times {T}_{SiO 2} - 0.3668 \times {( duty )}^{2} + 0.01115 \times {( LNcut )}^{2} - 0.0001333 \times {( LNcut )}^{3} + 5.911 \times {10}^{- 7} \times {( LNcut )}^{4} - 4.731 \times {( {T}_{IDT} \times ρ )}^{2} + 6.362 \times {( {T}_{IDT} \times ρ )}^{3} + 15.76 \times {( {T}_{L N} )}^{2} - 147.9 \times {( {T}_{L N} )}^{3} + 37 4.7 \times {( {T}_{L N} )}^{4} - 396.1 \times {( {T}_{L N} )}^{5} + 153.3 \times {( {T}_{L N} )}^{6} - 1.465 \times {( {T}_{SiO 2} )}^{2} + 1.185 \times {( {T}_{SiO 2} )}^{3} + 0.01565 \times duty \times LNcut + 0.6 \; 880 \times duty \times {T}_{IDT} \times ρ - 0.367 \times duty \times {T}_{L N} + 0.3 \; 453 \times duty \times {T}_{S i O 2} + 0.009192 \times LNcut \times {T}_{IDT} \times ρ - 0.03019 \times LNcut \times {T}_{L N} + 0.0 \; 02626 \times LNcut \times {T}_{S i O 2} + 0.1493 \times {T}_{IDT} \times ρ \times {T}_{L N} + 0.1977 \times {T}_{IDT} \times ρ \times {T}_{S i O 2} \qquad Formula 2$$

An acoustic wave device according to another example embodiment of the present invention includes a support substrate, a silicon oxide layer on the support substrate, a lithium niobate layer on the silicon oxide layer, and an IDT electrode on the lithium niobate layer and including AlCu, wherein, when a wavelength defined by an electrode finger pitch of the IDT electrode is denoted as λ, a thickness of the silicon oxide layer is more than or equal to about 0λ, and, when a thickness of the IDT electrode is denoted as T_{IDT} [λ], a duty ratio of the IDT electrode is denoted as duty, a cut-angle of the lithium niobate layer is denoted as LNcut [°], a thickness of the lithium niobate layer is denoted as T_{LN} [λ], a thickness of the silicon oxide layer is denoted as T_{SiO2} [λ], a fractional bandwidth of an SH mode is denoted as BW [%], and an electromechanical coupling coefficient in a Rayleigh mode is denoted as ksaw2 [%], values of T_{IDT}, duty, LNcut, T_{LN}, and T_{SiO2} are within ranges that enable BW derived from Formula 3 to be about 12% or less and ksaw2 derived from Formula 4 to be about 0.1% or less.

$$BW [ \% ] = 16.58 + 11.78 \times duty - 4.977 \times LNcut + 68.58 \times {T}_{IDT} + 240.3 \times {T}_{L N} + 13.76 \times {T}_{SiO 2} - 10.1 \times {( duty )}^{2} + 0.3515 \times {( LNcut )}^{2} - 0.01174 \times {( LNcut )}^{3} + 0.000207 \times {( LNcut )}^{4} - 0.00001865 \times {( LNcut )}^{5} + 6.771 \times {10}^{- 8} \times {( LNcut )}^{6} + 170.3 \times {( {T}_{IDT} )}^{2} - 3792 \times {( {T}_{IDT} )}^{3} + 10730 \times {( {T}_{IDT} )}^{4} - 1612 \times {( {T}_{L N} )}^{2} + 5724 \times {( {T}_{L N} )}^{3} - 10863 \times {( {T}_{L N} )}^{4} + 10555 \times {( {T}_{L N} )}^{5} - 4123 \times {( {T}_{L N} )}^{6} - 24.57 \times {( {T}_{SiO 2} )}^{2} + 25.57 \times {( {T}_{SiO 2} )}^{3} - 11.11 \times {( {T}_{SiO 2} )}^{4} - 0.0377 \times duty \times LNcut - 37.24 \times duty \times {T}_{IDT} + 3.097 \times duty \times {T}_{L N} - 0.6561 \times LNcut \times {T}_{IDT} - 0.3101 \times LNcut \times {T}_{L N} - 0.07464 \times LNcut \times {T}_{SiO 2} - 39.54 \times {T}_{IDT} \times {T}_{L N} + 21.64 \times {T}_{IDT} \times {T}_{SiO 2} - 9.508 \times {T}_{L N} \times {T}_{SiO 2} \qquad Formula 3$$

$$ksaw 2 [ \% ] = 4.639 - 0.3 \; 046 \times duty - 0.3965 \times LNcut + 0.9732 \times {T}_{IDT} + 3.956 \times {T}_{L N} + 0.1944 \times {T}_{SiO 2} - 0.3668 \times {( duty )}^{2} + 0.01115 \times {( LNcut )}^{2} - 0.0001333 \times {( LNcut )}^{3} + 0.000 \; 0005911 \times {( LNcut )}^{4} - 34.46 \times {( {T}_{IDT} )}^{2} + 125.0 \times {( {T}_{IDT} )}^{3} + 15. 76 \times {( {T}_{L N} )}^{2} - 147.9 \times {( {T}_{L N} )}^{3} + 374.7 \times {( {T}_{L N} )}^{4} - 396.1 \times {( {T}_{L N} )}^{5} + 153.3 \times {( {T}_{L N} )}^{6} - 1.465 \times {( {T}_{SiO 2} )}^{2} + 1.185 \times {( {T}_{S i O 2} )}^{3} + 0.01565 \times duty \times LNcut + 1.856 \times duty \times {T}_{IDT} - 0.367 \times duty \times {T}_{L N} + 0.3453 \times duty \times {T}_{SiO 2} + 0.02481 \times LNcut \times {T}_{IDT} - 0.03019 \times LNcut \times {T}_{L N} + 0.00262 \times LNcut \times {T}_{SiO 2} + 0.4029 \times {T}_{IDT} \times {T}_{L N} + 0 \text{.5335} \times {T}_{IDT} \times {T}_{SiO 2} \qquad Formula 4$$

With acoustic wave devices according to example embodiments of the present invention, Rayleigh mode spurious responses are reduced or prevented without unduly increasing the value of a fractional bandwidth.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a front cross-sectional view of an acoustic wave device according to a first example embodiment of the present invention.

FIG. 2 is a plan view of the acoustic wave device according to the first example embodiment of the present invention.

FIG. 3 is a graph showing the relation of BW of an SH mode with T_{LN} and T_{SiO2} when LNcut is about 45°.

FIG. 4 is a graph showing the relation of ksaw2 in a Rayleigh mode with T_{LN} and T_{SiO2} when LNcut is about 45°.

FIG. 5 is a graph showing the phase characteristic in an example embodiment of the present invention and the phase characteristic in a comparative example.

FIG. 6 is a graph showing the relation between T_{SiO2} and a normalized frequency at which a higher-order mode occurs.

FIG. 7 is a circuit diagram of a filter device according to a third example embodiment of the present invention.

### DETAILED DESCRIPTION OF THE EXAMPLE EMBODIMENTS

Specific example embodiments of the present invention will be described in detail below with reference to the drawings to clarify the present invention.

The example embodiments described in the present description are illustrative only and the structure in each example embodiment may be partially replaced or combined with the structure in another example embodiment.

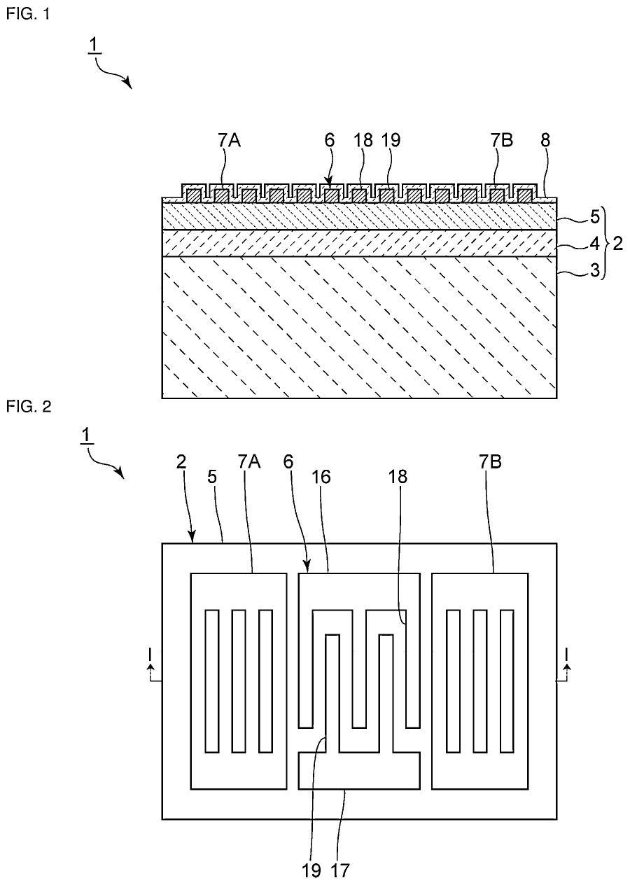

FIG. 1 is a front cross-sectional view of an acoustic wave device according to a first example embodiment of the invention.

The acoustic wave device 1 includes a piezoelectric substrate 2. The piezoelectric substrate 2 includes a support substrate 3, a silicon oxide layer 4, and a lithium niobate layer 5. The silicon oxide layer 4 is disposed on the support substrate 3. The lithium niobate layer 5 is disposed on the silicon oxide layer 4. In the present example embodiment, the silicon oxide used for the silicon oxide layer 4 is, for example, SiO₂. However, the composition of the silicon oxide used for the silicon oxide layer 4 is not limited to SiO₂.

An IDT electrode 6 is disposed on the lithium niobate layer 5. By applying an AC voltage to the IDT electrode 6, an acoustic wave is excited. The acoustic wave device 1 is a surface acoustic wave resonator configured such that an SH mode can be used as the main mode. In the acoustic wave device 1, a Rayleigh mode is a spurious response.

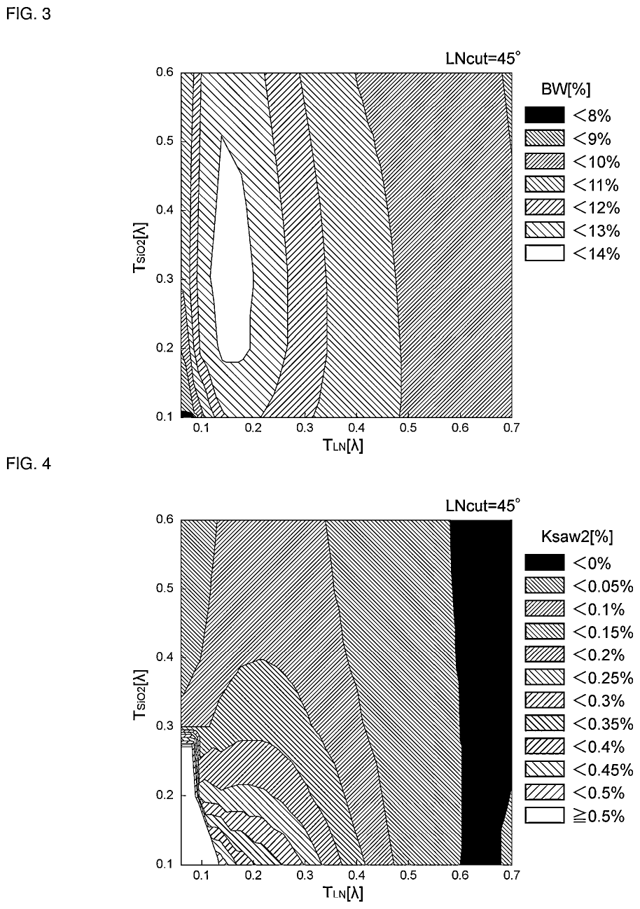

FIG. 2 is a plan view of the acoustic wave device according to the first example embodiment. FIG. 1 is a cross-sectional view taken along line I-I in FIG. 2. In FIG. 2, a dielectric film described later is omitted.

A pair of reflectors 7A and 7B are disposed on both sides, with respect to the direction of propagation of the acoustic wave, of the IDT electrode 6 on the lithium niobate layer 5. The IDT electrode 6 includes a first busbar 16, a second busbar 17, a plurality of first electrode fingers 18, and a plurality of second electrode fingers 19. The first busbar 16 and the second busbar 17 are opposed to each other. Ends of the plurality of first electrode fingers 18 are connected to the first busbar 16. Ends of the plurality of second electrode fingers 19 are connected to the second busbar 17. The plurality of first electrode fingers 18 and the plurality of second electrode fingers 19 are interdigitated with each other.

In the following description, the first electrode fingers 18 and the second electrode fingers 19 may be referred to simply as electrode fingers. In the present example embodiment, the extending direction of the plurality of electrode fingers is perpendicular or substantially perpendicular to the propagation direction of the acoustic wave. The dimension of each electrode finger in the propagation direction of the acoustic wave is defined as the width of the electrode finger. The wavelength defined by the electrode finger pitch of the IDT electrode 6 is denoted as λ. More specifically, the wavelength λ is about twice the electrode finger pitch. The electrode finger pitch is the center-to-center distance between adjacent ones of the first and second electrode fingers 18 and 19.

In the present description, a duty ratio is used as an indicator of the width size of the first and second electrode fingers 18 and 19 with respect to a region between the centers of adjacent ones of the first and second electrode fingers 18 and 19. More specifically, the duty ratio is the ratio of the total width of portions of the first and second electrode fingers 18 and 19 that are present in the above region to the dimension of the region in the propagation direction of the acoustic wave. In the present example embodiment, both of the electrode finger pitch and the width of the electrode fingers are constant. In this case, the duty ratios in the above regions of the IDT electrode 6 are each a value obtained by dividing the width of the electrode fingers by the electrode finger pitch. When the duty ratios are constant as described above, the duty ratios are referred to simply as the duty ratio of the IDT electrode 6 in the following description.

In the present example embodiment, the IDT electrode 6, the reflector 7A, and the reflector 7B each include a single-layer metal film. Specifically, the IDT electrode 6 and the reflectors are made of, for example, Al. However, the material of the IDT electrode 6 and the reflectors is not limited to the above material. Alternatively, the IDT electrode 6 and the reflectors may each include a multilayer metal film. In the present description, the phrase “a member is made of a material” is intended to encompass the case where the member includes impurities in such a trace amount that the electric characteristics of the acoustic wave device are not significantly impaired.

Returning to FIG. 1, a dielectric film 8 is disposed on the lithium niobate layer 5 so as to cover the IDT electrode 6. Since the dielectric film 8 is provided, the IDT electrode 6 is unlikely to break. In the present example embodiment, the dielectric film 8 is made of, for example, silicon oxide. The thickness of the dielectric film 8 is, for example, about 30 nm. However, the material and thickness of the dielectric film 8 are not limited to those described above. It is not always necessary to provide the dielectric film 8.

In the following description, the thickness of the IDT electrode 6 is denoted as T_{IDT} [λ], and the density of the IDT electrode 6 is denoted as ρ [g/cm³]. The duty ratio of the IDT electrode 6 is denoted as duty. The cut-angle of the lithium niobate layer 5 is denoted as LNcut [°], and the thickness of the lithium niobate layer 5 is denoted as T_{LN} [λ]. The thickness of the silicon oxide layer 4 is denoted as T_{SiO2} [λ]. The fractional bandwidth of the SH mode, which is the main mode, is denoted as BW [%], and the electromechanical coupling coefficient in the Rayleigh mode is denoted as ksaw2 [%]. The fractional bandwidth is represented by (|fa−fr|/fr)×100[%], where fr is the resonant frequency and fa is the anti-resonant frequency. The cut-angle of the lithium niobate layer 5 is more specifically a cut-angle for rotated Y-cut X-propagation lithium niobate.

A feature of the present example embodiment is that the values of T_{IDT}, ρ, duty, LNcut, T_{LN}, and T_{SiO2} are within ranges that enable BW derived from Formula 1 below to be about 12% or less and ksaw2 derived from Formula 2 below to be about 0.1% or less, for example. In this case, the Rayleigh mode spurious responses can be reduced or prevented without unduly increasing the value of the fractional bandwidth. The details will be described below.

Formula 1 is the relational expression of BW with T_{IDT}, ρ, duty, LNcut, T_{LN}, and T_{SiO2}. Formula 2 is the relational expression of ksaw2 with T_{IDT}, ρ, duty, LNcut, T_{LN}, and T_{SiO2}. Formulas 1 and 2 are as follows.

$$BW [ \% ] = 16.58 + 11.78 \times duty - 4.977 \times LNcut + 25.41 \times {T}_{IDT} \times ρ + 240.3 \times {T}_{L N} + 13.76 \times {T}_{SiO 2} - 10.1 \times {( duty )}^{2} + 0.3515 \times {( LNcut )}^{2} - 0.01174 \times {( LNcut )}^{3} + 0.000207 \times {( LNcut )}^{4} - 0.000001865 \times {( LNcut )}^{5} + 6.771 \times {10}^{- 9} \times {( LNcut )}^{6} + 23.38 \times {( {T}_{IDT} \times ρ )}^{2} - 192.9 \times {( {T}_{IDT} \times ρ )}^{3} + 202.2 \times {( {T}_{IDT} \times ρ )}^{4} - 1612 \times {( {T}_{L N} )}^{2} + 5724 \times {( {T}_{L N} )}^{3} - 10863 \times {( {T}_{L N} )}^{4} + 10555 \times {( {T}_{L N} )}^{5} - 4123 \times {( {T}_{L N} )}^{6} - 24.57 \times {( {T}_{SiO 2} )}^{2} + 25.57 \times {( {T}_{SiO 2} )}^{3} - 11.11 \times {( {T}_{SiO 2} )}^{4} - 0.0377 \times duty \times LNcut - 13.8 \times duty \times {T}_{IDT} \times ρ + 3.097 \times duty \times {T}_{L N} - 0.2431 \times LNcut \times {T}_{IDT} \times ρ - 0.3101 \times LNcut \times {T}_{L N} - 0.07464 \times LNcut \times {T}_{SiO 2} - 14.65 \times {T}_{IDT} \times ρ \times {T}_{L N} + 8.021 \times {T}_{IDT} \times ρ \times {T}_{SiO 2} - 9.508 \times {T}_{L N} \times {T}_{SiO 2} \qquad Formula 1$$

$$ksaw 2 [ \% ] = 4.839 - 0.3046 \times duty - 0.3965 \times LNcut + 0.3606 \times {T}_{IDT} \times ρ + 3.956 \times {T}_{L N} + 0.1 \; 944 \times {T}_{SiO 2} - 0.3668 \times {( duty )}^{2} + 0.01115 \times {( LNcut )}^{2} - 0.0001333 \times {( LNcut )}^{3} + 5.911 \times {10}^{- 7} \times {( LNcut )}^{4} - 4.731 \times {( {T}_{IDT} \times ρ )}^{2} + 6.362 \times {( {T}_{IDT} \times ρ )}^{3} + 15.76 \times {( {T}_{L N} )}^{2} - 147.9 \times {( {T}_{L N} )}^{3} + 37 4.7 \times {( {T}_{L N} )}^{4} - 396.1 \times {( {T}_{L N} )}^{5} + 153.3 \times {( {T}_{L N} )}^{6} - 1.465 \times {( {T}_{SiO 2} )}^{2} + 1.185 \times {( {T}_{SiO 2} )}^{3} + 0.01565 \times duty \times LNcut + 0.6 \; 880 \times duty \times {T}_{IDT} \times ρ - 0.367 \times duty \times {T}_{L N} + 0.3 \; 453 \times duty \times {T}_{S i O 2} + 0.009192 \times LNcut \times {T}_{IDT} \times ρ - 0.03019 \times LNcut \times {T}_{L N} + 0.0 \; 02626 \times LNcut \times {T}_{S i O 2} + 0.1493 \times {T}_{IDT} \times ρ \times {T}_{L N} + 0.1977 \times {T}_{IDT} \times ρ \times {T}_{S i O 2} \qquad Formula 2$$

Formulas 1 and 2 were derived by performing simulations on acoustic wave devices having the same or substantially the same layer structure as that in the first example embodiment. The materials of the members of the acoustic wave devices used for the simulations are as follows.
Support substrate: material . . . Si, orientation . . . (111) plane
Silicon oxide layer: material . . . SiO₂
Lithium niobate layer: material . . . LiNbO₃
IDT electrode: material . . . Al

By changing the design parameters within the following ranges, Formula 1 was derived. For example, the wavelength λ was set to about 5 μm. ρ is the density [g/cm³] of Al and is about 2.699 g/cm³. However, the value of ρ in Formula 1 may be set to, for example, the density [g/cm³] of any of the following metals according to the metal material of the IDT electrode used. Cu: about 8.96, Ag: about 10.05, Au: about 19.32, Pt: about 21.4, W: about 19.3, Ti: about 4.54, Ni: about 8.9, Cr: about 7.19, Mo: about 10.28.
T_{IDT}: about 0.04λ or more and about 0.16λ or less
LNcut: about 25° or more and about 70° or less
T_{LN}: about 0.06λ or more and about 0.7λ or less
T_{SiO2}: about 0λ or more and about 0.6λ or less
duty: about 0.4 or more and about 0.6 or less

Examples of the relationship of BW with T_{LN} and T_{SiO2} and the relationship of ksaw2 with T_{LN} and T_{SiO2} when LNcut is about 45° are shown in FIGS. 3 and 4.

FIG. 3 is a graph showing, for example, the relationship of BW of the SH mode with T_{LN} and T_{SiO2} for about 45° rotated Y-cut X-propagation (LNcut=about 45°). FIG. 4 is a graph showing the relation of ksaw2 in the Rayleigh mode with T_{LN} and T_{SiO2} when LNcut is about 45°.

As shown in FIG. 3, BW is dependent on T_{LN} and T_{SiO2}. Similarly, as shown in FIG. 4, ksaw2 is dependent on T_{LN} and T_{SiO2}. The relationship of BW with T_{LN} and T_{SiO2} and the relationship of ksaw2 with T_{LN} and T_{SiO2} vary for different LNcut values. These relationships are represented by Formulas 1 and 2 above.

In the first example embodiment, for example, the values of T_{IDT}, ρ, duty, LNcut, T_{LN}, and T_{SiO2} are within ranges that allow BW derived from Formula 1 to be about 12% or less. In this case, the value of the fractional bandwidth of the SH mode can be prevented from being excessively large. Moreover, the values of T_{IDT}, ρ, duty, LNcut, T_{LN}, and T_{SiO2} are within ranges that allow ksaw2 derived from Formula 2 to be about 0.1% or less. In this case, Rayleigh mode spurious responses can be reduced or prevented. These advantageous effects will be demonstrated by comparing the first example embodiment with a comparative example. The design parameters of the acoustic wave device in the first example embodiment used for the comparison are as follows.
Support substrate: material . . . Si, orientation . . . (111) plane
Silicon oxide layer: material . . . SiO₂, T_{SiO2} . . . about 0.1λ
Lithium niobate layer: material . . . LiNbO₃, LNcut . . . about 45°, T_{LN}: . . . about 0.6λ
IDT electrode: material . . . Al, ρ . . . about 2.699 g/cm³, T_{IDT} . . . about 0.08λ, duty . . . about 0.5, wavelength λ . . . about 5 μm

The design parameters in the comparative example are the same or substantially the same as those in the first example embodiment except that, for example, LNcut is about 25° and T_{LN} is about 0.2λ. With the design parameters in the comparative example, BW derived from Formula 1 is not about 12% or less, and ksaw2 derived from Formula 2 is not about 0.1% or less. The phase characteristic in the first example embodiment was compared with that in the comparative example.

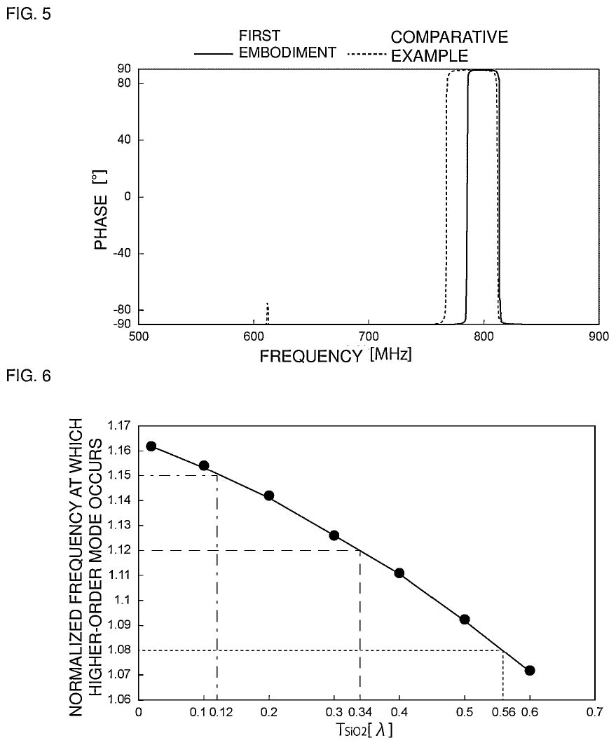

FIG. 5 is a graph showing the phase characteristic in the first example embodiment and the phase characteristic in the comparative example.

As shown in FIG. 5, in the comparative example, a Rayleigh mode spurious response occurred at around 600 MHz. However, in the first example embodiment, almost no Rayleigh mode spurious response occurred. Moreover, in the first example embodiment, the band from the resonant frequency to the anti-resonant frequency of the main mode is narrower than that in the comparative example. Therefore, in the first example embodiment, the value of the fractional bandwidth of the main mode is smaller than that in the comparative example.

As described above, in the first example embodiment, the Rayleigh mode spurious responses can be reduced or prevented without unduly increasing the value of the fractional bandwidth of the main mode. Therefore, when the acoustic wave device 1 in the first example embodiment is used for a filter device, good filter characteristics can be obtained. More specifically, in the acoustic wave device 1, the value of the fractional bandwidth is small. In this case, the steepness at the edge portion on the high-frequency or low-frequency side of the pass band of the filter device can be large. In the present description, the phrase “the steepness at an edge portion of the pass band is large” means that the change in frequency with respect to a given change in attenuation near the edge portion is small. In addition, the influence of the Rayleigh mode spurious responses on the filter characteristics can be reduced.

The cut-angle LNcut of the lithium niobate layer 5 is, for example, preferably about 40° or more. In this case, for example, as shown in FIG. 3, the ranges of the thickness T_{LN} of the lithium niobate layer 5 and the thickness T_{SiO2} of the silicon oxide layer 4 that allow the fractional bandwidth BW of the main mode to be less than about 12% can be widened.

The thickness T_{LN} of the lithium niobate layer 5 is, for example, preferably about 0.5λ or more. In this case, for example, as shown in FIGS. 3 and 4, the value of the fractional bandwidth BW of the SH mode, which is the main mode, and the value of the electromechanical coupling coefficient Ksaw2 in the Rayleigh mode can be more reliably reduced.

Simulations were further performed on acoustic wave devices 1 having the structure in the first example embodiment and having the respective silicon oxide layers 4 with different thicknesses T_{SiO2}. In this manner, the relationship between T_{SiO2} and the frequency at which a higher-order mode spurious response occurred was derived. The design parameters of the acoustic wave devices 1 in the simulations were the same or substantially the same as the design parameters of the acoustic wave device 1 for the comparison shown in FIG. 5 except for T_{SiO2}.

For example, the thickness T_{SiO2} of the silicon oxide layer 4 was changed in the range of about 0.02λ or more and about 0.6λ or less. More specifically, the thickness T_{SiO2} was changed in steps of about 0.08λ in the range of about 0.02λ or more and about 0.1λ or less and in steps of about 0.1λ in the range of about 0.1λ or more and about 0.6λ or less. In the following description, the frequency at which a higher-order mode occurs is represented as a normalized frequency normalized by the resonant frequency of the main mode.

FIG. 6 is a graph showing the relationship between T_{SiO2} and the normalized frequency at which a higher-order mode occurs.

As can be seen from FIG. 6, as the value of the thickness T_{SiO2} of the silicon oxide layer 4 decreases, the normalized frequency at which a higher-order mode occurs increases. T_{SiO2} is, for example, preferably about 0.56λ or less. In this case, the frequency at which a higher-order mode occurs can be more reliably increased to be higher than the anti-resonant frequency of the main mode. More specifically, the fractional bandwidth of the acoustic wave devices 1 used to derive the relationship in FIG. 6 was about 8%. In this case, the anti-resonant frequency normalized by the resonant frequency is about 1.08. When the thickness T_{SiO2} is about 0.56λ or less, the normalized frequency at which a higher-order mode occurs is about 1.08 or more. Therefore, by setting T_{SiO2} to about 0.56λ or less, the frequency at which a higher-order mode occurs can be easily increased to be higher than the anti-resonant frequency of the main mode.

T_{SiO2} is, for example, more preferably about 0.34λ or less. In this case, the frequency at which a higher-order mode occurs in the acoustic wave device 1 can be more reliably increased to be higher than the anti-resonant frequency of the main mode. More specifically, in the acoustic wave device 1 in the first example embodiment, the fractional bandwidth BW derived from Formula 1 is about 12% or less. Therefore, the anti-resonant frequency normalized by the resonant frequency is about 1.12 or less. When T_{SiO2} is about 0.34λ or less, the normalized frequency at which a higher-order mode occurs is about 1.12 or more. Therefore, when T_{SiO2} is about 0.34λ or less, the frequency at which a higher-order mode occurs can be easily increased to be higher than the anti-resonant frequency of the main mode in the acoustic wave devices 1 having the structure in the first example embodiment and having any fractional bandwidth.

T_{SiO2} is, for example, more preferably about 0.12λ or less. In this case, when the acoustic wave devices 1 having the structure in the first example embodiment are used for a parallel arm resonator and a series arm resonator of a ladder filter, the frequency at which a higher-order mode occurs in the parallel arm resonator can be more reliably higher than the anti-resonant frequency of the series arm resonator.

More specifically, in the series arm resonator and parallel arm resonator of the pass band of the ladder filter, the resonant frequency of the parallel arm resonator is lower than the resonant frequency of the series arm resonator. Therefore, a higher-order mode in the parallel arm resonator may occur between the resonant frequency and anti-resonant frequency of the series arm resonator. By setting the normalized frequency at which a higher-order mode occurs in the parallel arm resonator to about 1.15 or more, the frequency of the higher-order mode can be higher than the anti-resonant frequency of the series arm resonator. In the acoustic wave device 1 in the first example embodiment, when T_{SiO2} is about 0.12λ or less, the normalized frequency at which the higher-order mode occurs is about 1.15 or more. Therefore, when T_{SiO2} of the acoustic wave device 1 used as the parallel arm resonator is about 0.12λ or less, the frequency at which the higher-order mode occurs can be higher than the anti-resonant frequency of the series arm resonator.

When, for example, T_{SiO2} is about 0.02λ, the normalized frequency at which a higher-order mode occurs can be increased to about 1.16 or more.

In the acoustic wave device 1 in the first example embodiment, it is only necessary that the thickness T_{SiO2} of the silicon oxide layer 4 is about 0λ or more. When the thickness of the silicon oxide layer 4 is 0λ, the structure of the piezoelectric substrate 2 is the same as the structure in which the lithium niobate layer 5 is stacked directly on the support substrate 3.

In the first example embodiment, the IDT electrode includes a single-layer metal film. However, the IDT electrode may be a multilayer body including a plurality of electrode layers. In this case, the thicknesses of the electrode layers are denoted as t₁, t₂, . . . , tₙ, and then the thickness of the IDT electrode is represented by T_{IDT}=Σtₙ. The densities of the electrode layers are denoted as ρ₁, ρ₂, . . . , ρₙ, and then the density of the IDT electrode is represented by Σ (ρₙ×tₙ)/Σ tₙ. When the electrode layers are each made of an alloy, the densities of elements of the alloy are denoted as ρ₁, ρ₂, . . . , ρₙ, and their concentrations are denoted as ρ₁, ρ₂, . . . , ρₙ [%]. Then the density is represented by Σ (ρₙ×ρₙ). n in each formula using Σ is a natural number of 1 or more and less than or equal to the number of stacked layers.

When the IDT electrode is a multilayer body including a plurality of electrode layers, the density determined from Σ (ρₙ×tₙ)/Σ tₙ may be used as ρ in Formulas 1 and 2. When the electrode layer of the IDT electrode is an alloy layer, the density determined from Σ (ρₙ×ρₙ) may be used as ρ in Formulas 1 and 2. When the IDT electrode is a multilayer body including alloy layers, Σ (ρₙ×tₙ)/Σ tₙ and Σ (ρₙ×ρₙ) may be used in combination.

The structure of a second example embodiment of the present invention will next be described. The second example embodiment differs from the first example embodiment only in the material of the IDT electrode and the reflectors. Therefore, in the description of the second example embodiment, the figures and symbols used for the description of the first example embodiment will be used.

An IDT electrode 6 and reflectors in the second example embodiment include AlCu, for example. More specifically, in the present example embodiment, the IDT electrode 6 and the reflectors are made of AlCu, for example. One feature of the present example embodiment is, for example, that the values of T_{IDT}, duty, LNcut, T_{LN}, and T_{SiO2} are within ranges that allow BW derived from Formula 3 below to be about 12% or less and ksaw2 derived from Formula 4 below to be about 0.1% or less. In this case, Rayleigh mode spurious responses can be reduced or prevented without unduly increasing the value of the fractional bandwidth.

Formula 3 is a relational expression of BW with T_{IDT}, duty, LNcut, T_{LN}, and T_{SiO2}. Formula 4 is a relational expression of ksaw2 with T_{IDT}, duty, LNcut, T_{LN}, and T_{SiO2}. Formulas 3 and 4 are shown below. Formulas 3 and 4 were derived in the same manner as for Formulas 1 and 2. Specifically, Formulas 3 and 4 were derived by performing simulations on acoustic wave devices having the same layer structure as that in the first example embodiment.

$$BW [ \% ] = 16.58 + 11.78 \times duty - 4.977 \times LNcut + 68.58 \times {T}_{IDT} + 240.3 \times {T}_{L N} + 13.76 \times {T}_{SiO 2} - 10.1 \times {( duty )}^{2} + 0.3515 \times {( LNcut )}^{2} - 0.01174 \times {( LNcut )}^{3} + 0.000207 \times {( LNcut )}^{4} - 0.00001865 \times {( LNcut )}^{5} + 6.771 \times {10}^{- 8} \times {( LNcut )}^{6} + 170.3 \times {( {T}_{IDT} )}^{2} - 3792 \times {( {T}_{IDT} )}^{3} + 10730 \times {( {T}_{IDT} )}^{4} - 1612 \times {( {T}_{L N} )}^{2} + 5724 \times {( {T}_{L N} )}^{3} - 10863 \times {( {T}_{L N} )}^{4} + 10555 \times {( {T}_{L N} )}^{5} - 4123 \times {( {T}_{L N} )}^{6} - 24.57 \times {( {T}_{SiO 2} )}^{2} + 25.57 \times {( {T}_{SiO 2} )}^{3} - 11.11 \times {( {T}_{SiO 2} )}^{4} - 0.0377 \times duty \times LNcut - 37.24 \times duty \times {T}_{IDT} + 3.097 \times duty \times {T}_{L N} - 0.6561 \times LNcut \times {T}_{IDT} - 0.3101 \times LNcut \times {T}_{L N} - 0.07464 \times LNcut \times {T}_{SiO 2} - 39.54 \times {T}_{IDT} \times {T}_{L N} + 21.64 \times {T}_{IDT} \times {T}_{SiO 2} - 9.508 \times {T}_{L N} \times {T}_{SiO 2} \qquad Formula 3$$

$$ksaw 2 [ \% ] = 4.639 - 0.3 \; 046 \times duty - 0.3965 \times LNcut + 0.9732 \times {T}_{IDT} + 3.956 \times {T}_{L N} + 0.1944 \times {T}_{SiO 2} - 0.3668 \times {( duty )}^{2} + 0.01115 \times {( LNcut )}^{2} - 0.0001333 \times {( LNcut )}^{3} + 0.000 \; 0005911 \times {( LNcut )}^{4} - 34.46 \times {( {T}_{IDT} )}^{2} + 125.0 \times {( {T}_{IDT} )}^{3} + 15. 76 \times {( {T}_{L N} )}^{2} - 147.9 \times {( {T}_{L N} )}^{3} + 374.7 \times {( {T}_{L N} )}^{4} - 396.1 \times {( {T}_{L N} )}^{5} + 153.3 \times {( {T}_{L N} )}^{6} - 1.465 \times {( {T}_{SiO 2} )}^{2} + 1.185 \times {( {T}_{S i O 2} )}^{3} + 0.01565 \times duty \times LNcut + 1.856 \times duty \times {T}_{IDT} - 0.367 \times duty \times {T}_{L N} + 0.3453 \times duty \times {T}_{SiO 2} + 0.02481 \times LNcut \times {T}_{IDT} - 0.03019 \times LNcut \times {T}_{L N} + 0.00262 \times LNcut \times {T}_{SiO 2} + 0.4029 \times {T}_{IDT} \times {T}_{L N} + 0 \text{.5335} \times {T}_{IDT} \times {T}_{SiO 2} \qquad Formula 4$$

As described above, acoustic wave devices according to example embodiments of the present invention can be used for filter devices. An example of this will be described below.

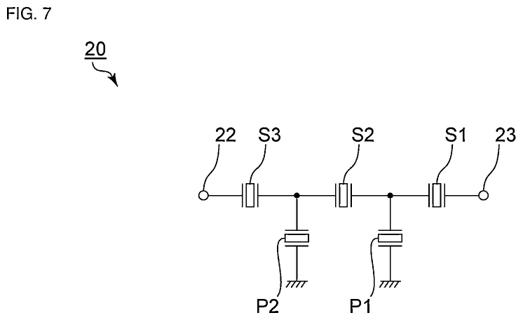

FIG. 7 is a circuit diagram of a filter device in a third example embodiment of the present invention.

The filter device 20 is, for example, a ladder filter. The filter device 20 includes a first signal terminal 22, a second signal terminal 23, and a plurality of resonators including a plurality of series arm resonators and a plurality of parallel arm resonators. In the filter device 20 in the present example embodiment, the plurality of resonators are each an acoustic wave device according to an example embodiment of the present invention. However, it is only necessary that at least one resonator is an acoustic wave device according to an example embodiment of the present invention.

In the present example embodiment, the first signal terminal 22 is an antenna terminal. The antenna terminal is connected to an antenna. The first signal terminal 22 and the second signal terminal 23 may be defined by, for example, electrode lands or wiring lines.

Specifically, the plurality of series arm resonators in the present example embodiment include a series arm resonator S1, a series arm resonator S2, and a series arm resonator S3. The plurality of series arm resonators are connected in series between the first signal terminal 22 and the second signal terminal 23. Specifically, the plurality of parallel arm resonators in the present example embodiment include a parallel arm resonator P1 and a parallel arm resonator P2. The parallel arm resonator P1 is connected between the ground potential and the connection point between the series arm resonators S1 and S2. The parallel arm resonator P2 is connected between the gourd potential and the connection point between the series arm resonators S2 and S3.

However, the circuit configuration of filter devices according to example embodiments of the present invention are not limited to the above circuit configuration. When the filter device is a ladder filter, it is only necessary that the filter device includes at least one series arm resonator and at least one parallel arm resonator. Alternatively, the filter device may include a longitudinally coupled resonator acoustic wave filter. In this case, it is only necessary that the filter device includes at least one acoustic wave device according to an example embodiment of the present invention that is a series arm resonator or a parallel arm resonator.

In the present example embodiment, acoustic wave devices according to example embodiments of the present invention are used as the series arm resonators and the parallel arm resonators. In this case, the value of the fractional bandwidth of each resonator can be small, and the Rayleigh mode spurious responses can be reduced or prevented. Therefore, the steepness at the edge portions of the pass band can be large, and the influence of the Rayleigh mode on the filter characteristics can be reduced.

Preferably, at least one parallel arm resonator is an acoustic wave device according to an example embodiment of the present invention, and the thickness T_{SiO2} of the silicon oxide layer is, for example, about 0.12λ or less. In this case, the frequency at which a higher-order mode occurs in the parallel arm resonator can be higher than the anti-resonant frequency of the series arm resonators, as described above.

Even with a structure including another dielectric film between the silicon oxide layer and the support substrate, the advantageous effects of example embodiments of the present invention can be obtained.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
a silicon oxide layer on the support substrate;
a lithium niobate layer on the silicon oxide layer; and
an IDT electrode on the lithium niobate layer; wherein
when a wavelength defined by an electrode finger pitch of the IDT electrode is denoted as λ, a thickness of the silicon oxide layer is more than or equal to about 0λ; and
when a thickness of the IDT electrode is denoted as T_{IDT} [λ], a density of the IDT electrode is denoted as ρ [g/cm³], a duty ratio of the IDT electrode is denoted as duty, a cut-angle of the lithium niobate layer is denoted as LNcut [°], a thickness of the lithium niobate layer is denoted as T_{LN} [λ], a thickness of the silicon oxide layer is denoted as T_{SiO2} [λ], a fractional bandwidth of an SH mode is denoted as BW [%], and an electromechanical coupling coefficient in a Rayleigh mode is denoted as ksaw2 [%], values of T_{IDT}, ρ, duty, LNcut, T_{LN}, and T_{SiO2} are within ranges enabling BW derived from Formula 1 to be about 12% or less and ksaw2 derived from Formula 2 to be about 0.1% or less:
$$BW [ \% ] = 16.58 + 11.78 \times duty - 4.977 \times LNcut + 25.41 \times {T}_{IDT} \times ρ + 240.3 \times {T}_{L N} + 13.76 \times {T}_{SiO 2} - 10.1 \times {( duty )}^{2} + 0.3515 \times {( LNcut )}^{2} - 0.01174 \times {( LNcut )}^{3} + 0.000207 \times {( LNcut )}^{4} - 0.000001865 \times {( LNcut )}^{5} + 6.771 \times {10}^{- 9} \times {( LNcut )}^{6} + 23.38 \times {( {T}_{IDT} \times ρ )}^{2} - 192.9 \times {( {T}_{IDT} \times ρ )}^{3} + 202.2 \times {( {T}_{IDT} \times ρ )}^{4} - 1612 \times {( {T}_{L N} )}^{2} + 5724 \times {( {T}_{L N} )}^{3} - 10863 \times {( {T}_{L N} )}^{4} + 10555 \times {( {T}_{L N} )}^{5} - 4123 \times {( {T}_{L N} )}^{6} - 24.57 \times {( {T}_{SiO 2} )}^{2} + 25.57 \times {( {T}_{SiO 2} )}^{3} - 11.11 \times {( {T}_{SiO 2} )}^{4} - 0.0377 \times duty \times LNcut - 13.8 \times duty \times {T}_{IDT} \times ρ + 3.097 \times duty \times {T}_{L N} - 0.2431 \times LNcut \times {T}_{IDT} \times ρ - 0.3101 \times LNcut \times {T}_{L N} - 0.07464 \times LNcut \times {T}_{SiO 2} - 14.65 \times {T}_{IDT} \times ρ \times {T}_{L N} + 8.021 \times {T}_{IDT} \times ρ \times {T}_{SiO 2} - 9.508 \times {T}_{L N} \times {T}_{SiO 2} ; and \qquad Formula 1$$
$$ksaw 2 [ \% ] = 4.839 - 0.3046 \times duty - 0.3965 \times LNcut + 0.3606 \times {T}_{IDT} \times ρ + 3.956 \times {T}_{L N} + 0.1 \; 944 \times {T}_{SiO 2} - 0.3668 \times {( duty )}^{2} + 0.01115 \times {( LNcut )}^{2} - 0.0001333 \times {( LNcut )}^{3} + 5.911 \times {10}^{- 7} \times {( LNcut )}^{4} - 4.731 \times {( {T}_{IDT} \times ρ )}^{2} + 6.362 \times {( {T}_{IDT} \times ρ )}^{3} + 15.76 \times {( {T}_{L N} )}^{2} - 147.9 \times {( {T}_{L N} )}^{3} + 37 4.7 \times {( {T}_{L N} )}^{4} - 396.1 \times {( {T}_{L N} )}^{5} + 153.3 \times {( {T}_{L N} )}^{6} - 1.465 \times {( {T}_{SiO 2} )}^{2} + 1.185 \times {( {T}_{SiO 2} )}^{3} + 0.01565 \times duty \times LNcut + 0.6 \; 880 \times duty \times {T}_{IDT} \times ρ - 0.367 \times duty \times {T}_{L N} + 0.3 \; 453 \times duty \times {T}_{S i O 2} + 0.009192 \times LNcut \times {T}_{IDT} \times ρ - 0.03019 \times LNcut \times {T}_{L N} + 0.0 \; 02626 \times LNcut \times {T}_{S i O 2} + 0.1493 \times {T}_{IDT} \times ρ \times {T}_{L N} + 0.1977 \times {T}_{IDT} \times ρ \times {T}_{S i O 2} . \qquad Formula 2$$

2. The acoustic wave device according to claim 1, wherein T_{SiO2} is about 0.56λ or less.

3. The acoustic wave device according to claim 1, wherein T_{SiO2} is about 0.34λ or less.

4. The acoustic wave device according to claim 1, wherein T_{SiO2} is about 0.12λ or less.

5. The acoustic wave device according to claim 1, wherein the IDT electrode includes a single-layer metal film.

6. The acoustic wave device according to claim 5, wherein the single-layer metal film includes Al.

7. The acoustic wave device according to claim 1, further comprising a dielectric film on the lithium niobate layer and covering the IDT electrode.

8. The acoustic wave device according to claim 7, wherein the dielectric film includes silicon oxide.

9. The acoustic wave device according to claim 7, wherein a thickness of the dielectric film is about 30 nm.

10. An acoustic wave device comprising:
a support substrate;
a silicon oxide layer on the support substrate;
a lithium niobate layer on the silicon oxide layer; and
an IDT electrode on the lithium niobate layer and including AlCu; wherein
when a wavelength defined by an electrode finger pitch of the IDT electrode is denoted as λ, a thickness of the silicon oxide layer is more than or equal to about 0λ; and
when a thickness of the IDT electrode is denoted as T_{IDT} [λ], a duty ratio of the IDT electrode is denoted as duty, a cut-angle of the lithium niobate layer is denoted as LNcut [°], a thickness of the lithium niobate layer is denoted as T_{LN} [λ], a thickness of the silicon oxide layer is denoted as T_{SiO2} [λ], a fractional bandwidth of an SH mode is denoted as BW [%], and an electromechanical coupling coefficient in a Rayleigh mode is denoted as ksaw2 [%], then values of T_{IDT}, duty, LNcut, T_{LN}, and T_{SiO2} are within ranges that enables BW derived from Formula 3 to be about 12% or less and ksaw2 derived from Formula 4 to be about 0.1% or less:
$$BW [ \% ] = 16.58 + 11.78 \times duty - 4.977 \times LNcut + 68.58 \times {T}_{IDT} + 240.3 \times {T}_{L N} + 13.76 \times {T}_{SiO 2} - 10.1 \times {( duty )}^{2} + 0.3515 \times {( LNcut )}^{2} - 0.01174 \times {( LNcut )}^{3} + 0.000207 \times {( LNcut )}^{4} - 0.00001865 \times {( LNcut )}^{5} + 6.771 \times {10}^{- 8} \times {( LNcut )}^{6} + 170.3 \times {( {T}_{IDT} )}^{2} - 3792 \times {( {T}_{IDT} )}^{3} + 10730 \times {( {T}_{IDT} )}^{4} - 1612 \times {( {T}_{L N} )}^{2} + 5724 \times {( {T}_{L N} )}^{3} - 10863 \times {( {T}_{L N} )}^{4} + 10555 \times {( {T}_{L N} )}^{5} - 4123 \times {( {T}_{L N} )}^{6} - 24.57 \times {( {T}_{SiO 2} )}^{2} + 25.57 \times {( {T}_{SiO 2} )}^{3} - 11.11 \times {( {T}_{SiO 2} )}^{4} - 0.0377 \times duty \times LNcut - 37.24 \times duty \times {T}_{IDT} + 3.097 \times duty \times {T}_{L N} - 0.6561 \times LNcut \times {T}_{IDT} - 0.3101 \times LNcut \times {T}_{L N} - 0.07464 \times LNcut \times {T}_{SiO 2} - 39.54 \times {T}_{IDT} \times {T}_{L N} + 21.64 \times {T}_{IDT} \times {T}_{SiO 2} - 9.508 \times {T}_{L N} \times {T}_{SiO 2} ; and \qquad Formula 3$$
$$ksaw 2 [ \% ] = 4.639 - 0.3 \; 046 \times duty - 0.3965 \times LNcut + 0.9732 \times {T}_{IDT} + 3.956 \times {T}_{L N} + 0.1944 \times {T}_{SiO 2} - 0.3668 \times {( duty )}^{2} + 0.01115 \times {( LNcut )}^{2} - 0.0001333 \times {( LNcut )}^{3} + 0.000 \; 0005911 \times {( LNcut )}^{4} - 34.46 \times {( {T}_{IDT} )}^{2} + 125.0 \times {( {T}_{IDT} )}^{3} + 15. 76 \times {( {T}_{L N} )}^{2} - 147.9 \times {( {T}_{L N} )}^{3} + 374.7 \times {( {T}_{L N} )}^{4} - 396.1 \times {( {T}_{L N} )}^{5} + 153.3 \times {( {T}_{L N} )}^{6} - 1.465 \times {( {T}_{SiO 2} )}^{2} + 1.185 \times {( {T}_{S i O 2} )}^{3} + 0.01565 \times duty \times LNcut + 1.856 \times duty \times {T}_{IDT} - 0.367 \times duty \times {T}_{L N} + 0.3453 \times duty \times {T}_{SiO 2} + 0.02481 \times LNcut \times {T}_{IDT} - 0.03019 \times LNcut \times {T}_{L N} + 0.00262 \times LNcut \times {T}_{SiO 2} + 0.4029 \times {T}_{IDT} \times {T}_{L N} + 0 \text{.5335} \times {T}_{IDT} \times {T}_{SiO 2} . \qquad Formula 4$$

11. The acoustic wave device according to claim 10, further comprising a dielectric film on the lithium niobate layer and covering the IDT electrode.

12. The acoustic wave device according to claim 11, wherein the dielectric film includes silicon oxide.

13. The acoustic wave device according to claim 11, wherein a thickness of the dielectric film is about 30 nm.
